(19) United States
(12) Patent Application Publication
(10) Pub. No.: US 2026/0223556 A1
(43) Pub. Date: Jul. 30, 2026

(54) DISPLAY DEVICE AND METHOD FOR MANUFACTURING SAME

(71) Applicant: Sharp Display Technology Corporation, Kameyama City, Mie (JP)

(72) Inventors: Shunsuke KOBAYASHI, Kameyama City, Mie (JP); Yujiro TAKEDA, Kameyama City, Mie (JP)

(21) Appl. No.: 19/147,440

(22) PCT Filed: Jan. 13, 2023
(86) PCT No.: PCT/JP2023/000824

§ 371 Date: Jul. 11, 2025

(51) Int. Cl. H10K 59/131; H10K 59/12

(52) U.S. Cl. CPC H10K 59/131; H10K 59/1201

(57) ABSTRACT

A TFT layer provided on a resin substrate includes the following: a plurality of lower wiring layers provided so as to extend in parallel with each other in a first direction in a plan view; an interlayer insulating film provided so as to cover the plurality of lower wiring layers; and a plurality of upper wiring layers provided on the interlayer insulating film so as to extend in parallel with each other in a second direction intersecting with the plurality of lower wiring layers. Between the plurality of upper wiring layers adjacent to each other, at least one end of the plurality of lower wiring layers in the second direction includes one or more protrusions or one or more recesses.

### TECHNICAL FIELD

The present invention relates to a display device and a method for manufacturing the same.

### BACKGROUND ART

Attention has been recently drawn to self-emission organic EL display devices incorporating organic electroluminescence (hereinafter, also referred to as EL) elements, as display devices alternative to liquid crystal displays. Flexible organic EL display devices have been proposed that are provided with, on a flexible resin substrate for instance, a TFT layer including a plurality of thin-film transistors (hereinafter, also referred to as “TFTs”) for driving an organic EL element for each subpixel constituting its display region.

For example, Patent Literature 1 proposes a display device including an active matrix substrate in which a plurality of TFTs is arranged on a resin substrate without alignment deviation.

### CITATION LIST

### Patent Literature

Patent Literature 1: Japanese Unexamined Patent Application Publication No. 2003-174171.

### SUMMARY OF INVENTION

### Technical Field

By the way, flexible organic EL display devices sometimes cause leakage between lower wiring layers in their TFT layers each having a stacked structure in which a lower wiring layer and an upper wiring layer are stacked so as to intersect each other with an interlayer insulating film interposed therebetween; such leakage occurs due to a residue of the lower wiring layer. To prevent this leakage failure, a rework step is performed after patterning the lower wiring layer for instance, to remove the residue. In the rework step, a rework resist is formed and patterned, through photolithography for instance, onto the substrate surface including the lower wiring layer, followed by dry etching to remove a residue of the lower wiring layer in a portion not covered with a resist.

Here, an alignment deviation of the rework resist occurs in some cases because TFT miniaturization has progressed and accurate photomask positioning is considerably difficult with the performance of photolithography. If the lower wiring layer not covered with the rework resist is etched due to the alignment deviation, its etching end is turned into a steep tapered surface. In the TFT layer, in which an interlayer insulating film and an upper wiring layer are sequentially formed on the substrate surface including such a lower wiring layer in a step subsequent to the rework step, a residue of the upper wiring layer remains unremoved in some cases on the interlayer insulating film corresponding to the steep etching end of the lower wiring layer. In these cases, the residue of the upper wiring layer may constitute a leakage path to cause leakage between the upper wiring layers; there is room for improvement.

The present invention has been made in view of this problem. It is an object of the present invention to prevent leakage between upper wiring layers in a TFT layer having a stacked structure in which a lower wiring layer and an upper wiring layer are stacked so as to intersect with an interlayer insulating film interposed therebetween, even when a residue of the upper wiring layer remains.

### Solution to Problem

To achieve the above object, a display device according to the present invention includes the following: a base substrate; and a thin-film transistor layer provided on the base substrate. The thin-film transistor layer includes a plurality of lower wiring layers provided so as to extend in parallel with each other in a first direction in a plan view, an interlayer insulating film provided so as to cover the plurality of lower wiring layers, and a plurality of upper wiring layers provided on the interlayer insulating film so as to extend in parallel with each other in a second direction intersecting with the plurality of lower wiring layers. Between the plurality of upper wiring layers adjacent to each other, at least one end of the plurality of lower wiring layers in the second direction includes one or more protrusions protruding with respect to the first direction in the plan view, or one or more recesses recessed with respect to the first direction in the plan view.

In a method for manufacturing a display device according to the present invention, the display device includes a base substrate, and a thin-film transistor layer provided on the base substrate. The thin-film transistor layer includes a plurality of lower wiring layers provided so as to extend in parallel with each other in a first direction in a plan view, an interlayer insulating film provided so as to cover the plurality of lower wiring layers, and a plurality of upper wiring layers provided on the interlayer insulating film so as to extend in parallel with each other in a second direction intersecting with the plurality of lower wiring layers. The method includes a step of forming the thin-film transistor layer onto the base substrate. The step of forming the thin-film transistor layer includes the following: a step of forming the plurality of lower wiring layers by forming a lower metal film onto a substrate surface including layers below the plurality of lower wiring layers, followed by patterning the lower metal film; a step of forming the interlayer insulating film onto the substrate surface including the plurality of lower wiring layers, so as to cover the plurality of lower wiring layers; and a step of forming the plurality of upper wiring layers by forming an upper metal film onto the substrate surface including the interlayer insulating film, followed by patterning the upper metal film. The step of forming the plurality of lower wiring layers includes forming one or more protrusions protruding with respect to the first direction in the plan view, or one or more recesses recessed with respect to the first direction in the plan view, onto at least one end of the plurality of lower wiring layers in the second direction between the plurality of upper wiring layers adjacent to each other.

### Advantageous Effect of Invention

The present invention can prevent leakage between upper wiring layers in a TFT layer having a stacked structure in which a lower wiring layer and an upper wiring layer are stacked so as to intersect with an interlayer insulating film interposed therebetween, even when a residue of the upper wiring layer remains.

### BRIEF DESCRIPTION OF DRAWINGS

FIG. 1 is a plan view of the schematic configuration of an organic EL display device according to a first embodiment of the present invention.

FIG. 2 is a plan view of a display region of the organic EL display device according to the first embodiment of the present invention.

FIG. 3 is a cross-sectional view of the display region of the organic EL display device according to the first embodiment of the present invention.

FIG. 4 is an enlarged plan view of lower wiring layers after patterning-resist removal, in a step of forming a TFT layer in a method for manufacturing the organic EL display device according to the first embodiment of the present invention.

FIG. 5 is an enlarged plan view of a wiring structure after rework-resist patterning, in the step of forming the TFT layer in the method for manufacturing the organic EL display device according to the first embodiment of the present invention.

FIG. 6 is a cross-sectional view of the wiring structure after the rework-resist patterning, in the step of forming the TFT layer in the method for manufacturing the organic EL display device according to the first embodiment of the present invention, and FIG. 6 is a cross-sectional view taken along line VI-VI in FIG. 5.

FIG. 7 is an enlarged plan view of a wiring structure after rework etching, in the step of forming the TFT layer in the method for manufacturing the organic EL display device according to the first embodiment of the present invention.

FIG. 8 is a cross-sectional view of the wiring structure after the rework etching, in the step of forming the TFT layer in the method for manufacturing the organic EL display device according to the first embodiment of the present invention, and FIG. 8 is a cross-sectional view taken along line VIII-VIII in FIG. 7.

FIG. 9 is an enlarged plan view of the wiring structure after rework-resist removal, followed by formation of an interlayer insulating film, in the step of forming the TFT layer in the method for manufacturing the organic EL display device according to the first embodiment of the present invention.

FIG. 10 is a cross-sectional view of the wiring structure after the rework-resist removal, followed by the formation of the interlayer insulating film, in the step of forming the TFT layer in the method for manufacturing the organic EL display device according to the first embodiment of the present invention, and FIG. 10 is a cross-sectional view taken along line X-X in FIG. 9.

FIG. 11 is an enlarged plan view of the wiring structure including upper wiring layers after patterning, in the step of forming the TFT layer in the method for manufacturing the organic EL display device according to the first embodiment of the present invention.

FIG. 12 is a cross-sectional view of the wiring structure including the upper wiring layers after the patterning, in the step of forming the TFT layer in the method for manufacturing the organic EL display device according to the first embodiment of the present invention, and FIG. 12 is a cross-sectional view taken along line XII-XII in FIG. 11.

FIG. 13 is an enlarged plan view of a first modification of the lower wiring layer constituting the TFT layer of the organic EL display device according to the first embodiment of the present invention, and FIG. 13 corresponds to FIG. 11.

FIG. 14 is an enlarged plan view of a second modification of the lower wiring layer constituting the TFT layer of the organic EL display device according to the first embodiment of the present invention, and FIG. 14 corresponds to FIG. 11.

FIG. 15 is an enlarged plan view of a third modification of the lower wiring layer constituting the TFT layer of the organic EL display device according to the first embodiment of the present invention, and FIG. 15 corresponds to FIG. 11.

FIG. 16 is an enlarged plan view of a fourth modification of the lower wiring layer constituting the TFT layer of the organic EL display device according to the first embodiment of the present invention, and FIG. 16 corresponds to FIG. 11.

FIG. 17 is an equivalent circuit diagram of a pixel circuit of the organic EL display device according to the first embodiment of the present invention.

FIG. 18 is a cross-sectional view of an organic EL layer constituting the organic EL display device according to the first embodiment of the present invention.

FIG. 19 is an enlarged plan view of a wiring structure including upper wiring layers after patterning, in a step of forming a TFT layer in a method for manufacturing an organic EL display device according to a second embodiment of the present invention.

### DESCRIPTION OF EMBODIMENTS

The embodiments of the present invention will be detailed on the basis of the drawings. It is noted that the present invention is not limited to the following embodiments.

### First Embodiment

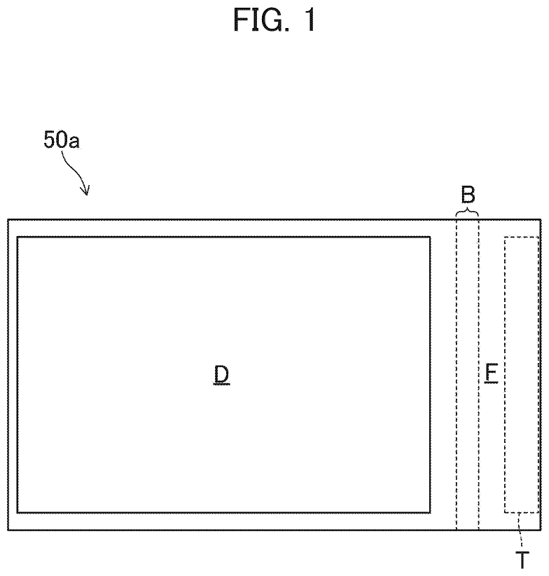

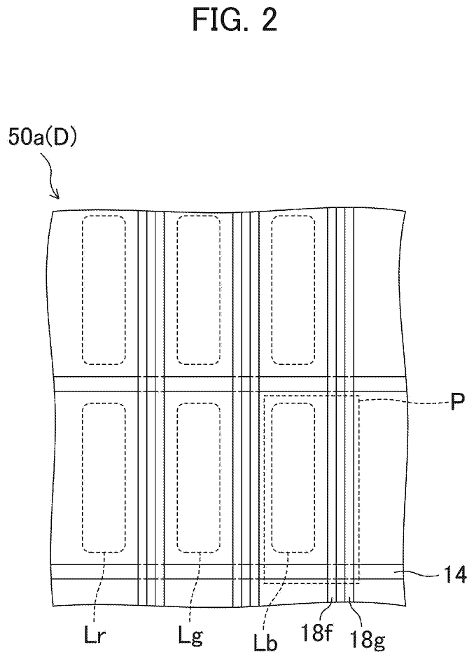

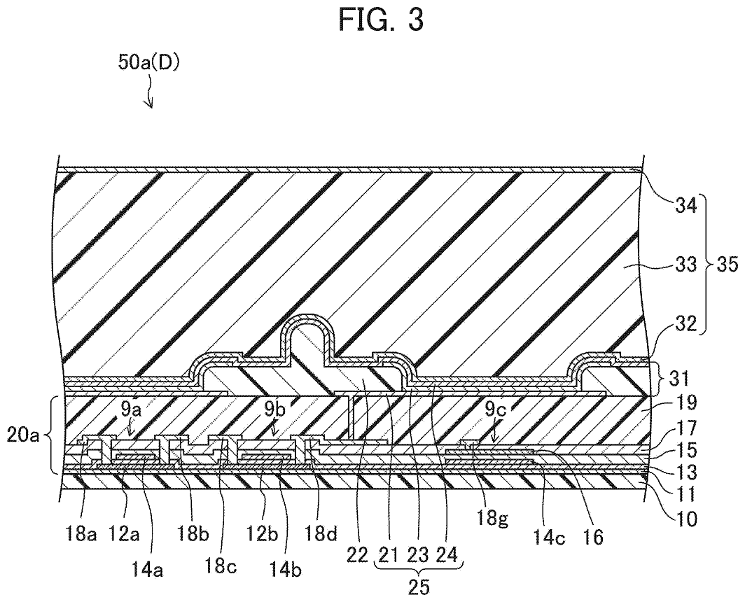

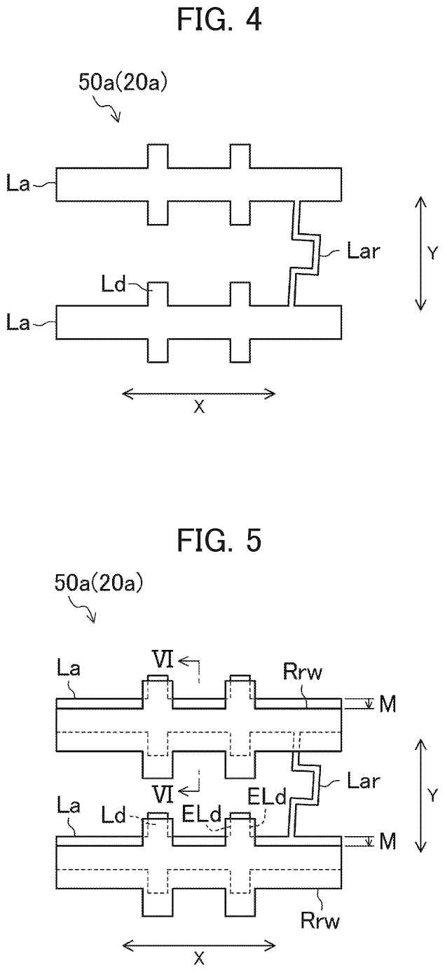

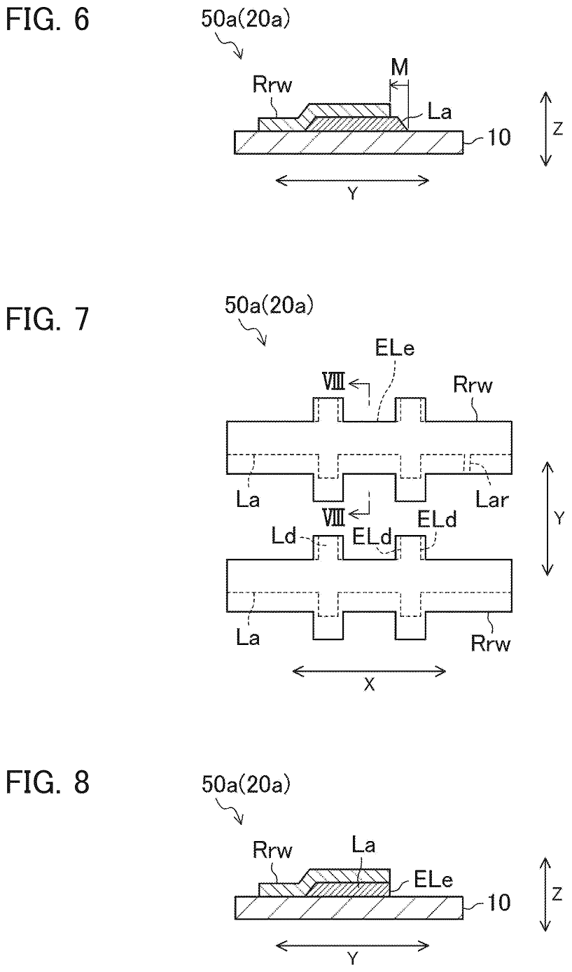

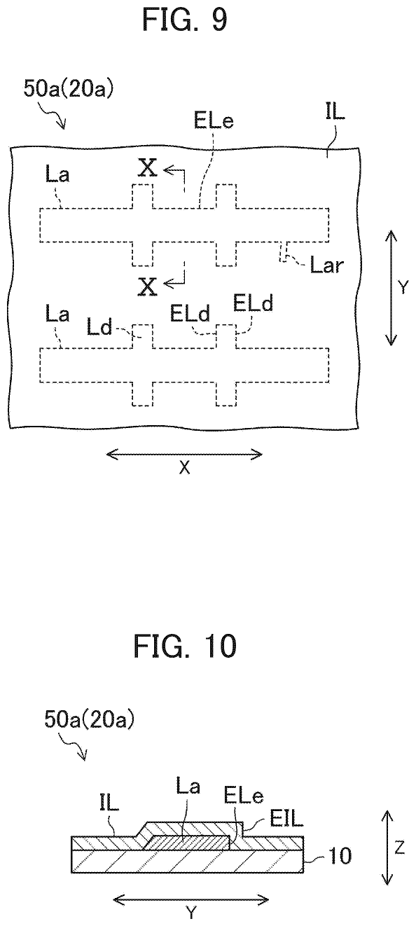

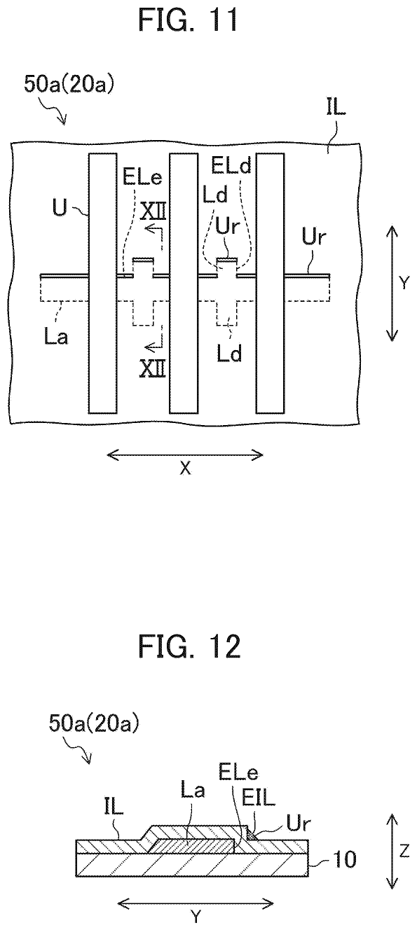

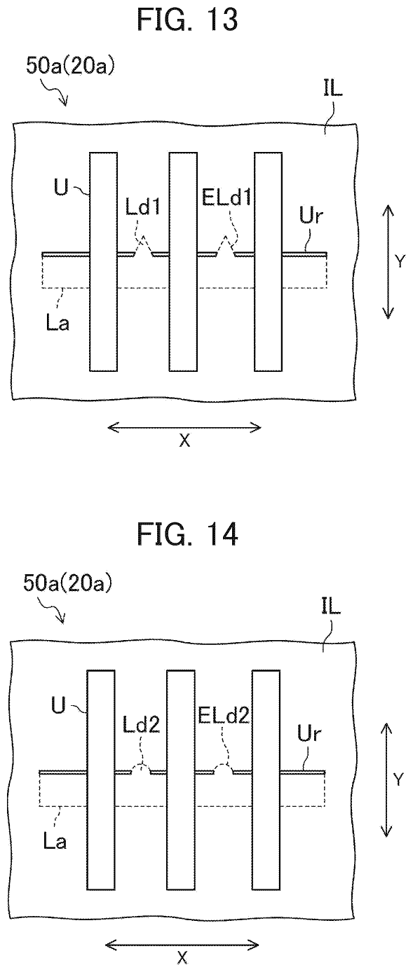

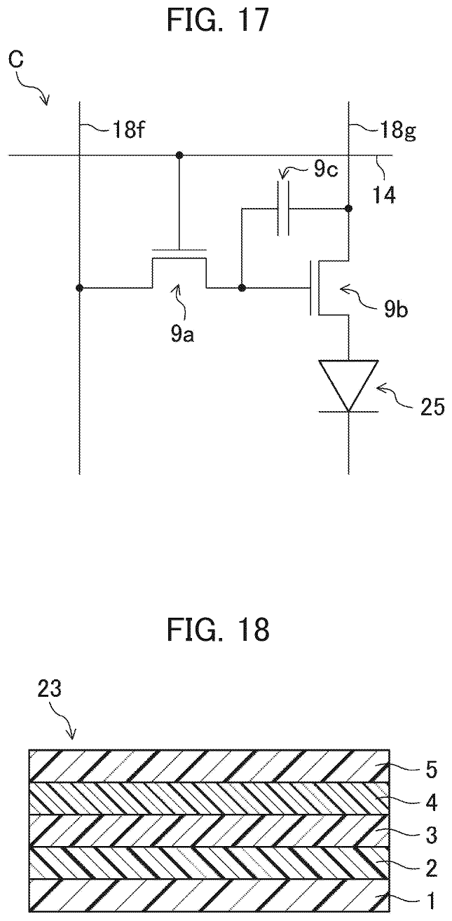

FIGS. 1 to 18 illustrate a display device according to a first embodiment of the present invention. It is noted that the following embodiments will describe an organic EL display device including organic EL elements by way of example, as a display device including light-emitting elements. Here, FIG. 1 is a plan view of the schematic configuration of an organic EL display device 50a according to this embodiment. FIG. 2 is a plan view of a display region D of the organic EL display device 50a. FIG. 3 is a cross-sectional view of the display region D of the organic EL display device 50a. FIG. 4 is an enlarged plan view of lower wiring layers La after patterning-resist removal, in a step of forming a TFT layer in a method for manufacturing the organic EL display device 50a. FIG. 5 is an enlarged plan view of a wiring structure after patterning of a rework resist Rrw, in the step of forming the TFT layer in the method for manufacturing the organic EL display device 50a. FIG. 6 is a cross-sectional view taken along line VI-VI in FIG. 5. FIG. 7 is an enlarged plan view of the wiring structure after rework etching, in the step of forming the TFT layer in the method for manufacturing the organic EL display device 50a. FIG. 8 is a cross-sectional view taken along line VIII-VIII in FIG. 7. FIG. 9 is an enlarged plan view of the wiring structure after removal of the rework resist Rrw, followed by formation of an interlayer insulating film IL, in the step of forming the TFT layer in the method for manufacturing the organic EL display device 50a. FIG. 10 is a cross-sectional view taken along line X-X in FIG. 9. FIG. 11 is an enlarged plan view of the wiring structure including upper wiring layers U after patterning, in the step of forming the TFT layer in the method for manufacturing the organic EL display device 50a. FIG. 12 is a cross-sectional view taken along line XII-XII in FIG. 11. FIGS. 13 to 16 are enlarged plan views of first to fourth modifications of the lower wiring layer La constituting a TFT layer 20a of the organic EL display device 50a, and these drawing correspond to FIG. 11. FIG. 17 is an equivalent circuit diagram of a pixel circuit C of the organic EL display device 50a. FIG. 18 is a cross-sectional view of an organic EL layer 23 constituting the organic EL display device 50a. It is noted that FIGS. 6, 8, 10, and 12 omit layers below the lower wiring layers La. Further, the following directions are defined in the organic EL display device 50a: a first direction X (see FIGS. 4, 5, 7, 9, 11, and 13 to 16) parallel to a base substrate surface, which will be described later on; a second direction Y (see FIGS. 4 to 16) perpendicular to the first direction X and parallel to the base substrate surface; and a third direction Z (see FIGS. 6, 8, 10, and 12) perpendicular to the first direction X and second direction Y.

As illustrated in FIG. 1, the organic EL display device 50a includes the display region D provided in the form of, for instance, a rectangle and provided for image display, and a frame region F provided in the form of a frame around the display region D. It is noted that although this embodiment describes the rectangular display region D by way of example, this rectangular shape includes substantially rectangular shapes, such as a shape with an arc-shaped side, a shape with an arc-shaped corner, and a shape with part of a side being notched.

The display region D includes a plurality of subpixels P arranged in matrix, as illustrated in FIG. 2. Further, as illustrated in FIG. 2, a subpixel P having a red light-emitting region Lr for red display, a subpixel P having a green light-emitting region Lg for green display, and a subpixel P having a blue light-emitting region Lb for blue display, for instance, are provided in the display region D so as to be adjacent to one another. It is noted that the display region D is structured such that for instance, three adjacent subpixels P having the red light-emitting region Lr, green light-emitting region Lg, and blue light-emitting region Lb constitute a single pixel. It is also noted that the arrangement of the subpixels P is non-limiting; examples include a Pen Tile matrix and a stripe matrix.

The frame region F includes a terminal section T provided at one end (the right end in FIG. 1) so as to extend in one direction (the longitudinal direction in FIG. 1). The frame region F also includes, as illustrated in FIG. 1, a bending section B provided between the terminal section T and the display region D so as to extend in one direction (the longitudinal direction in FIG. 1); here, the bending section B is, for instance, 180° (U-shape) bendable about a bending axis, which is in the longitudinal direction in FIG. 1.

As illustrated in FIG. 3, the organic EL display device 50a includes a resin substrate 10 provided as a base substrate, and the TFT layer 20a provided on the resin substrate 10.

The resin substrate 10 contains, but not limited to, polyimide resin for instance.

The TFT layer 20a includes the following as illustrated in FIG. 3: a base coat film 11 provided on the resin substrate 10; a plurality of first TFTs 9a, a plurality of second TFTs 9b, and a plurality of capacitors 9c provided on the base coat film 11 and each provided for a corresponding one of the subpixels P; and a flattening film 19 provided on the first TFTs 9a, second TFTs 9b, and capacitors 9c. Here, the TFT layer 20a includes the following sequentially stacked on the resin substrate 10, as illustrated in FIG. 3: the base coat film 11; semiconductor layers 12a and 12b; a gate insulating film 13; a first wiring layer, including gate lines 14 (see FIG. 2), gate electrodes 14a and 14b, and a lower conductive layer 14c; a first interlayer insulating film 15; a second wiring layer, including an upper conductive layer 16; a second interlayer insulating film 17; a third wiring layer, including source lines 18f (see FIG. 2), source electrodes 18a and 18c, drain electrodes 18b and 18d, and power supply lines 18g; and the flattening film 19. The TFT layer 20a also includes, as illustrated in FIGS. 2 and 17, a plurality of gate lines 14 provided so as to extend in parallel with each other in the lateral direction in the drawings. The TFT layer 20a also includes, as illustrated in FIGS. 2 and 17, a plurality of source lines 18f provided so as to extend in parallel with each other in a direction intersecting with (orthogonal to) the plurality of gate lines 14, i.e., in the longitudinal direction in the drawings. The TFT layer 20a also includes, as illustrated in FIGS. 2 and 17, a plurality of power supply lines 18g provided so as to extend in parallel with each other in the longitudinal direction in the drawings. It is noted that each power supply line 18g is provided so as to be adjacent to a corresponding one of the source lines 18f, as illustrated in FIG. 2. Further, the TFT layer 20a includes, as illustrated in FIG. 17, the first TFT 9a, second TFT 9b, and capacitor 9c constituting a pixel circuit C in each subpixel P. The pixel circuits C are arranged in matrix in one-to-one correspondence with the subpixels P.

The base coat film 11, the gate insulating film 13, the first interlayer insulating film 15, and the second interlayer insulating film 17 are formed from an inorganic insulating monolayer film or inorganic insulating multilayer film of, for instance, silicon nitride (SiNx, where x is a positive number), silicon oxide (SiO₂), silicon oxide nitride (SiON), or other materials. The semiconductor layers 12a and 12b are formed from, for instance, a low-temperature polysilicon film, an In—Ga—Zn—O oxide semiconductor film, or other films. The first, second, and third wiring layers are formed from a monolayer film of a metal, such as molybdenum (Mo), titanium (Ti,), aluminum (Al), copper (Cu), or tungsten (W), or is formed from a multilayer film of metals, such as Mo (upper layer)-Al (middle layer)-Mo (lower layer), Ti—Al—Ti, Al (upper layer)-Ti (lower layer), Cu—Mo, or Cu—Ti. It is noted that the third wiring layer is preferably formed from a metal multilayer film of Ti—Al—Ti or other materials.

The first TFTs 9a and the second TFTs 9b are p-type TFTs in which semiconductor layers 12a and 12b, which will be described later, are doped with an impurity, such as boron.

The first TFT 9a in each subpixel P is electrically connected to the corresponding gate line 14 and source line 18f, as illustrated in FIG. 17. Further, the first TFT 9a includes the following sequentially provided on the base coat film 11, as illustrated in FIG. 3: the semiconductor layer 12a, the gate insulating film 13, the gate electrode 14a, the first interlayer insulating film 15, the second interlayer insulating film 17, the source electrode 18a, and the drain electrode 18b. Here, the semiconductor layer 12a is provided in the form of an island on the base coat film 11, as illustrated in FIG. 3, and has, for instance, a channel region, a source region, and a drain region. Further, the gate insulating film 13 is provided so as to cover the semiconductor layer 12a, as illustrated in FIG. 3. Further, the gate electrode 14a is provided on the gate insulating film 13 so as to overlap the channel region of the semiconductor layer 12a, as illustrated in FIG. 3. Further, the first interlayer insulating film 15 and the second interlayer insulating film 17 are sequentially provided so as to cover the gate electrode 14a, as illustrated in FIG. 3. Further, the source electrode 18a and the drain electrode 18b are provided on the second interlayer insulating film 17 so as to be spaced from each other, as illustrated in FIG. 3. Further, as illustrated in FIG. 3, the source electrode 18a and the drain electrode 18b are electrically connected to the source region and drain region of the semiconductor layer 12a, respectively, via respective contact holes formed in the stack of the gate insulating film 13, first interlayer insulating film 15, and second interlayer insulating film 17.

The second TFT 9b in each subpixel P is electrically connected to the corresponding first TFT 9a and power supply line 18g, as illustrated in FIG. 17. Further, the second TFT 9b includes the following sequentially provided on the base coat film 11, as illustrated in FIG. 3: the semiconductor layer 12b, the gate insulating film 13, the gate electrode 14b, the first interlayer insulating film 15, the second interlayer insulating film 17, the source electrode 18c, and the drain electrode 18d. Here, the semiconductor layer 12b is provided in the form of an island on the base coat film 11, as illustrated in FIG. 3, and has, for instance, a channel region, a source region, and a drain region. Further, the gate insulating film 13 is provided so as to cover the semiconductor layer 12b, as illustrated in FIG. 3. Further, the gate electrode 14b is provided on the gate insulating film 13 so as to overlap the channel region of the semiconductor layer 12b, as illustrated in FIG. 3. Further, the first interlayer insulating film 15 and the second interlayer insulating film 17 are sequentially provided so as to cover the gate electrode 14b, as illustrated in FIG. 3. Further, the source electrode 18c and the drain electrode 18d are provided on the second interlayer insulating film 17 so as to be spaced from each other, as illustrated in FIG. 3. Further, the source electrode 18c and the drain electrode 18d are electrically connected to the source region and drain region of the semiconductor layer 12b, respectively, via respective contact holes formed in the stack of the gate insulating film 13, first interlayer insulating film 15, and second interlayer insulating film 17.

It is noted that although this embodiment has described, by way of example, the first TFTs 9a and second TFTs 9b of top-gate structure, the first TFTs 9a and the second TFTs 9b may be TFTs of bottom-gate structure.

The capacitor 9c in each subpixel P is electrically connected to the corresponding first TFT 9a and power supply line 18g, as illustrated in FIG. 17. Here, the capacitor 9c includes the following as illustrated in FIG. 3: the lower conductive layer 14c formed in the same layer with the same material as the gate electrodes 14a and 14b; the first interlayer insulating film 15 provided so as to cover the lower conductive layer 14c; and the upper conductive layer 16 provided on the first interlayer insulating film 15 so as to overlap the lower conductive layer 14c. It is noted that the upper conductive layer 16 is electrically connected to the power supply line 18g via a contact hole formed in the second interlayer insulating film 17, as illustrated in FIG. 3.

The flattening film 19 has a flat surface in the display region D and contains, but not limited to, an organic resin material, such as polyimide resin or acrylic resin, or a polysiloxane spin-on-glass (SOG) material.

Here, the TFT layer 20a constituting the organic EL display device 50a has a stack of, in sequence, a plurality of lower wiring layers La, an interlayer insulating film IL, and a plurality of upper wiring layers U.

The plurality of lower wiring layers La is provided so as to extend in parallel with each other in the first direction X (the lateral direction in FIG. 4) in plan view, as illustrated in FIG. 4 (see also FIGS. 5 to 16). In other words, the lower wiring layers La extend in a straight line in the first direction X. The lower wiring layers La are formed, for instance, in the same layer with the same material as the first wiring layer (such as the gate lines 14, the gate electrodes 14a and 14b, and the lower conductive layer 14c) or the second wiring layer (such as the upper conductive layer 16), both of which are provided in the TFT layer 20a constituting the display region D. The lower wiring layers La formed in the same layer as the first wiring layer are provided on the gate insulating film 13, which constitutes the TFT layer 20a. The lower wiring layers La formed in the same layer as the second wiring layer are provided on the first interlayer insulating film 15, which constitutes the TFT layer 20a.

The interlayer insulating film I1 is provided so as to cover the plurality of lower wiring layers La, as illustrated in FIGS. 9 to 12 (see also FIGS. 13 to 16). Examples of the interlayer insulating film IL include, but not limited to, the first interlayer insulating film 15 covering the lower wiring layers La formed in the same layer as the first wiring layer, and the second interlayer insulating film 17 covering the lower wiring layers La formed in the same layer as the second wiring layer.

The upper wiring layers U are wiring layers located above the lower wiring layers La. The plurality of upper wiring layers U is provided on the interlayer insulating film IL so as to extend in parallel with each other in the second direction Y orthogonal to the first direction X, in which the lower wiring layers La extend, and is parallel to the surface of the resin substrate 10, as illustrated in FIGS. 11 and 12 (see also FIGS. 13 to 16). In other words, the upper wiring layers U extend in a straight line in the first direction X. That is, the upper wiring layers U intersect with the lower wiring layers La. The upper wiring layers U are formed, for instance, in the same layer with the same material as the second wiring layer (such as the upper conductive layer 16) or the third wiring layer (such as the source lines 18f, the source electrodes 18a and 18c, the drain electrodes 18b and 18d, and the power supply lines 18g) (see FIG. 3). The upper wiring layers U formed in the same layer as the second wiring layer are provided on the first interlayer insulating film 15 as the interlayer insulating film IL. The lower wiring layers La formed in the same layer as the third wiring layer are provided on the second interlayer insulating film 17 as the interlayer insulating film IL.

It is noted that the lower wiring layers La, the interlayer insulating film IL, and the upper wiring layers U are not limited to those described above, and that these layers and film are applicable to a stack of, in sequence, a metal layer, an insulating layer, and a metal layer. For instance, these layers and film are applied to a stack of the lower wiring layers La formed in the same layer as the first wiring layer, the interlayer insulating film IL formed from a stack of the first interlayer insulating film 15 and second interlayer insulating film 17, and the upper wiring layers U formed in the same layer as the third wiring layer. Further, when a fourth wiring layer (e.g., a conductive layer between the third wiring layer and first electrodes 21) above the third wiring layer is provided, the upper wiring layers U may be formed in the same layer with the same material as the fourth wiring layer.

The lower wiring layers La, the interlayer insulating film IL, and the upper wiring layers U are sequentially formed in a step of forming a TFT layer, which will be described later on. For instance, a lower metal film to constitute the lower wiring layers La is formed onto the substrate surface on which layers below the lower wiring layers La are formed, and the lower metal film then undergoes patterning to form the plurality of lower wiring layers La. Here, as illustrated in FIG. 4, a residue Lar of the lower wiring layer La (a film residue of the lower metal film) remain unremoved in some cases between the adjacent lower wiring layers La after the removal of a patterning resist (not shown) for the lower metal film. If the residue Lar constitutes a leakage path to thus electrically connect the adjacent lower wiring layers La together, leakage occurs between the lower wiring layers La. To prevent this leakage failure, the step of forming the TFT layer includes a rework step for removing the residue Lar of the lower wiring layer La after forming the lower wiring layers La (a step of forming lower wiring layers, which will be described later on).

In the rework step, the first step is forming the rework resist Rrw onto a substrate (hereinafter, referred to as the resin substrate 10) surface including the lower wiring layers La, followed by patterning the resist Rrw. At this time, an alignment deviation M may occur in which the patterned resist Rrw deviates from the lower wiring layers La to one side (the lower side in FIG. 5, the left side in FIG. 6), as illustrated in FIGS. 5 and 6.

If rework etching is performed with the alignment deviation M occurring in the rework resist Rrw, not only the residue Lar of the lower wiring layer La not covered with the resist Rrw (i.e., not overlapping in plan view) is removed, but also one end of the lower wiring layer La (the upper end in FIG. 7, the right end in FIG. 8) is removed. Consequently, as illustrated in FIG. 8, the end surface (hereinafter, also referred to as an etching end surface) of an etched end (hereinafter, also referred to as an etching end) ELe of the lower wiring layer La tapers further, and its inclined surface has a steeper inclination than the surface (an unetched patterned surface) of the other end (the lower end in FIG. 7, the left end in FIG. 8). If such an alignment deviation M of the rework resist Rrw occurs in the rework step for the lower wiring layers La, the etching end ELe is formed that has a steep tapered etching end surface, on one side of the lower wiring layer La with the alignment deviation M.

The rework step is followed by, as illustrated in FIGS. 9 and 10, forming the interlayer insulating film IL onto the substrate surface after the removal of the rework resist Rrw so as to cover the lower wiring layers La (a step of forming an interlayer insulating film, which will be described later on). At this time, as illustrated in FIG. 10, an end EIL having a steep tapered inclined surface is formed on one side of the interlayer insulating film IL (the upper side in FIG. 9, the right side in FIG. 10) along the steep end surface shape of the etching end ELe formed in the lower wiring layer La; the steep tapered inclined surface of the end EIL is steeper than that in the other end (the lower side in FIG. 9, the left side in FIG. 10).

The next is forming an upper metal film to constitute the upper wiring layers U onto the substrate surface including the interlayer insulating film IL, followed by patterning the upper metal film to form the upper wiring layers U (a step of forming upper wiring layers, which will be described later on). At this time, a residue Ur of the upper wiring layer U (a film residue of the upper metal film) remains unremoved in some cases, after the rework etching, on the end EIL having a steep surface formed in the interlayer insulating film IL, as illustrated in FIGS. 11 and 12. In these cases, the residue Ur and the upper wiring layers U adjacent to each other via the residue Ur are electrically connected together at their intersection, thereby generating leakage between the upper wiring layers U. It is noted that as illustrated in FIGS. 11 and 12, the residue Ur of the upper wiring layer U is formed at one (the upper end in FIG. 11, the right end in FIG. 12) of the ends of the lower wiring layer La (the upper and lower ends in FIG. 11, the right and left ends in FIG. 12) in the width direction corresponding to the etching end ELe of the lower wiring layer La and to the end EIL of the interlayer insulating film IL.

If such an alignment deviation M of the rework resist Rrw as described above occurs in the rework step for the lower wiring layers La, the residue Ur remains on the surface of the steep end EIL of the interlayer insulating film IL after the formation of the upper wiring layers U, as illustrated in FIGS. 11 and 12. The end EIL of the interlayer insulating film IL is formed along the etching end ELe (an end with the alignment deviation M) of the lower wiring layer La. Here, the lower wiring layer La and the upper wiring layer U intersect, as illustrated in FIG. 11, and thus, the residue Ur extending in parallel to the lower wiring layer La in the first direction X and the upper wiring layer U also intersect. Moreover, the residue Ur and the upper wiring layer U, which are formed in the same layer, are electrically connected together at their intersection. In such a conventional TFT-layer wiring structure as described above, the residue Ur of the upper wiring layer U constitutes a leakage path resulting from the alignment deviation M of the rework resist Rrw of the lower wiring layer La, thereby generating leakage between the upper wiring layers U.

Here, unlike the conventional wiring structure, the TFT layer 20a constituting the organic EL display device 50a according to this embodiment includes protrusions Ld at both ends (both sides) of the lower wiring layer La in the width direction between the plurality of upper wiring layers U adjacent to each other, as illustrated in FIG. 11 (see also FIGS. 4, 5, 7, and 9).

The protrusions Ld are portions provided continuously in the lower wiring layer La, and protruding with respect to the first direction X in plan view. The protrusions have their protruding distal ends protruding toward the second direction Y (toward the outside of the lower wiring layer La in the width direction). The protrusions are each formed in a rectangular shape in plan view.

Here, the protrusions Ld are portions of the lower wiring layer La departing from a straight line along each end of the lower wiring layer La in the width direction (i.e., a straight line parallel to the first direction X in which each end extends). As illustrated in FIG. 11, the protrusions Ld include their ends (hereinafter, also referred to as dividing ends) ELd extending in a direction (the second direction Y in FIG. 11) turned around from the first direction X in which the etchig end ELe of the lower wiring layer La extends. The end surface (etching end surface) of the lower wiring layer La close to the dividing end ELd is divided (separated) by the dividing end ELd so as to be spaced in the second direction Y to be thus discontinuous in the first direction X. As illustrated in FIG. 11 (see also FIG. 12), the end EIL of the interlayer insulating film IL, which is formed along the etching end ELe (etching end surface) of the lower wiring layer La, and the residue Ur of the upper wiring layer U, which is formed on the end EIL, are also divided (separated) by the dividing end ELd so as to be spaced in the second direction Y to be thus discontinuous in the first direction X. Here, the dividing ends ELd of the protrusions Ld (both of the right and left ends in FIGS. 5 and 7) are covered with the rework resist Rrw with the alignment deviation M generated in the rework step, as illustrated in FIGS. 5 and 7. The dividing ends ELd hence do not undergo rework etching and have no steep tapered surface after the rework etching. As a result, the residue Ur of the upper wiring layer U does not remain on an end corresponding to the dividing end ELd of the interlayer insulating film IL, as illustrated in FIG. 11. As described, the protrusions Ld of the lower wiring layer La are portions that divide the etching ends ELe (its straightness), which is formed due to the alignment deviation M of the rework resist Rrw in the rework step for the lower wiring layers La, and are portions in which no steep tapered surface (end surface) is formed. To be specific, each protrusion Ld at the dividing end ELd divides the straightness of the etching end ELe by turning around to a direction (the second direction Y in FIG. 11) different from a direction (the first direction X in FIG. 11) along the etching end surface of the etching end ELe. In the wiring structure of the TFT layer 20a constituting the organic EL display device 50a, the leakage path formed by the residue Ur is blocked at the protrusion Ld (its dividing end ELd) even when the residue Ur of the upper wiring layer U remains; this prevents leakage between the upper wiring layers U.

It is noted that although the protrusions Ld in this embodiment are provided at both ends (both sides) of the lower wiring layer La in the width direction, at least one of the ends (sides) may include the protrusion Ld. For instance, when the direction in which the alignment deviation M of the rework resist Rrw can occur in the rework step for the lower wiring layers La is determined on one side in design, protrusions Ld1 to Ld3 may be provided only on this side where the alignment deviation M can occur, as illustrated in FIGS. 13 to 15. It is noted that the protrusions Ld are preferably provided on both sides of the lower wiring layer La when the above determination is difficult to make. It is also noted that although a single protrusion Ld (or a single recess, which will be described later on) is provided at one end of the lower wiring layer La in the width direction between the plurality of upper wiring layers U adjacent to each other, at least one protrusion Ld needs to be provided; a plurality of protrusions Ld may be provided.

### Modifications of Protrusion or Recess

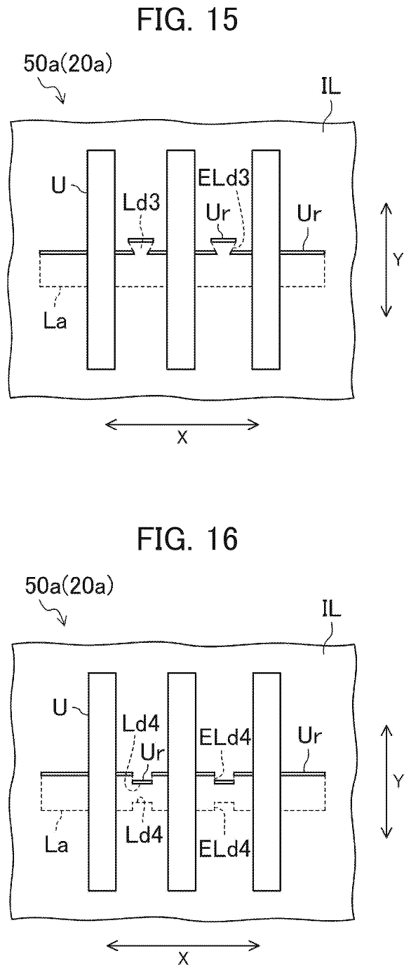

The protrusions Ld in this embodiment are each formed in a rectangular shape in plan view by way of example. The protrusion's shape may be the protrusion Ld1 (see FIG. 13) having a triangular shape in plan view, the protrusion Ld2 (see FIG. 14) having a semicircular shape in plan view, the protrusion Ld3 (see FIG. 15) having an inverted-trapezoidal shape (rectangular shape) in plan view, or other shapes. Recesses recessed with respect to the first direction X (toward the inside of the lower wiring layer La in the width direction) in plan view may be provided instead of the protrusions Ld, as illustrated in FIG. 16. The recess's shape may be a recess Ld4 (see FIG. 16) having a rectangular shape in plan view, an inverted-triangular shape in plan view, a semicircular shape in plan view, a (inverted) trapezoidal shape in plan view, or other shapes. In any of the first to fourth modifications, dividing ends ELd1 to ELd4 are formed in the protrusions Ld1 to Ld3 and the recess Ld4, respectively, as illustrated in FIG. 16. The straightness of the etching end ELe of the lower wiring layer La is divided at the dividing ends ELd1 to ELd4.

The organic EL display device 50a includes the following as illustrated in FIG. 3: an organic EL element layer 31 provided above the TFT layer 20a, as a light-emitting element layer constituting the display region D; and a sealing film 35 provided on the organic EL element layer 31.

As illustrated in FIG. 3, the organic EL element layer 31 includes a plurality of organic EL elements 25 as a plurality of light-emitting elements arranged in matrix in correspondence with the plurality of subpixels P.

The organic EL elements 25 include the following as illustrated in FIG. 3: a plurality of first electrodes 21 provided on the flattening film 19; a plurality of organic EL layers 23 provided in the individual subpixels P on the first electrodes 21; and a second electrode 24 provided on the organic EL layers 23 and shared among the plurality of subpixels P. Further, the organic EL elements 25 are covered with the sealing film 35, as illustrated in FIG. 3.

The first electrodes 21 are provided in matrix on the flattening film 19 so as to correspond to the plurality of subpixels P, as illustrated in FIG. 3. Further, each first electrode 21 is electrically connected to the drain electrode 18d (or source electrode 18c) of the corresponding second TFT 9b via a contact hole formed in the flattening film 19, as illustrated in FIG. 3. Further, the first electrode 21 has the function of injecting holes (positive holes) into the organic EL layer 23. Further, the first electrode 21 more desirably contains a material having a large work function in order to improve the efficiency of hole injection into the organic EL layer 23. Here, examples of the material of the first electrode 21 include metal materials, such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, the first electrode 21 may contain, but not limited to, alloy of astatine (At) and astatine oxide (AtO₂). Furthermore, the first electrode 21 may contain, but not limited to, conductive oxide, including tin oxide (SnO), zinc oxide (ZnO), indium tin oxide (ITO), and indium zinc oxide (IZO). Further, the first electrode 21 may be formed by stacking multiple layers containing the above materials. It is noted that examples of a compound material having a large work function include indium tin oxide (ITO) and indium zinc oxide (IZO).

The first electrode 21 has a perimeter covered with an edge cover 22 provided in a lattice shape and shared among the plurality of subpixels P. Here, examples of the material of the edge cover 22 include photosensitive positive resin materials, such as polyimide resin, acrylic resin, polysiloxane resin, and novolak resin, and polysiloxane spin-on-glass (SOG) materials. As illustrated in FIG. 3, a part of the surface of the edge cover 22 protrudes upward in the drawing to constitute pixel photo-spacers provided in the form of islands.

The organic EL layers 23 are provided in matrix on the individual first electrodes 21 so as to correspond to the plurality of subpixels P, as illustrated in FIG. 3. Here, each organic EL layer 23 includes, as illustrated in FIG. 18, a hole injection layer 1, a hole transport layer 2, an emission layer 3, an electron transport layer 4, and an electron injection layer 5 stacked sequentially on the first electrode 21.

The hole injection layer 1 is also called an anode buffer layer, and has the function of bringing the energy levels of the first electrode 21 and organic EL layer 23 close to each other to improve the efficiency of hole injection from the first electrode 21 into the organic EL layer 23. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the first electrode 21 to the organic EL layer 23. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The emission layer 3 is a region in which holes and electrons are respectively injected from the first electrode 21 and second electrode 24 applied with voltage, and in which the holes and electrons recombine together. Here, the emission layer 3 contains a material having high efficiency of light emission. Moreover, examples of the material of the emission layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzthiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, a quinacridone derivative, rubrene, poly-p-phenylenevinylene, and polysilane.

The electron transport layer 4 has the function of moving electrons to the emission layer 3 efficiently. Here, examples of the material of the electron transport layer 4 include organic compounds, such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the second electrode 24 and organic EL layer 23 close to each other to improve the efficiency of electron injection from the second electrode 24 into the organic EL layer 23. This function can lower voltage for driving the organic EL element 25. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF₂), strontium fluoride (SrF₂), and barium fluoride (BaF₂), as well as aluminum oxide (Al₂O₃) and strontium oxide (SrO).

The second electrode 24 is provided so as to cover the individual organic EL layers 23 and the edge cover 22, as illustrated in FIG. 3. Further, the second electrode 24 has the function of injecting electrons into the organic EL layers 23. Further, the second electrode 24 more desirably contains a material having a small work function in order to improve the efficiency of electron injection into the organic EL layers 23. Here, examples of the material of the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Moreover, the second electrode 24 may contain, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Further, the second electrode 24 may contain conductive oxide, such as tin oxide (SnO), zinc oxide (ZnO), indium tin oxide (ITO), or indium zinc oxide (IZO). Further, the second electrode 24 may be formed by stacking multiple layers containing the above materials. It is noted that examples of the material having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

The sealing film 35 includes the following as illustrated in FIG. 3: a first inorganic insulating sealing film 32 provided so as to cover the second electrode 24; an organic sealing film 33 provided on the first inorganic insulating sealing film 32; and a second inorganic insulating sealing film 34 provided so as to cover the organic sealing film 33, and the sealing film 35 has the function of protecting the organic EL layers 23 from water, oxygen, and other foreign substances. Here, the first inorganic insulating sealing film 32 and the second inorganic insulating sealing film 34 contain an inorganic material, such as silicon oxide (SiO₂), aluminum oxide (Al₂O₃), silicon nitride (SiNx, where x is a positive number) such as trisilicon tetranitride (Si₃N₄), or silicon carbonitride (SiCN). Further, the organic sealing film 33 contains an organic material, such as acrylic resin, polyurea resin, parylene resin, polyimide resin, or polyamide resin.

The foregoing organic EL display device 50a is configured to display an image through the following process in each subpixel P: a gate signal is input to the first TFT 9a via the gate line 14 to turn on the first TFT 9a; a data signal is written into the gate electrode 14b of the second TFT 9b and the capacitor 9c via the source line 18f, and a current coming from the power supply line 18g and corresponding to the gate voltage of the second TFT 9b is supplied to the organic EL layer 23, so that the emission layer 3 of the organic EL layer 23 emits light. It is noted that in the organic EL display device 50a, the emission layer 3 continues to emit light until a gate signal in the next frame is input, because the capacitor 9c retains the gate voltage of the second TFT 9b even when the first TFT 9a is turned off.

A method for manufacturing the organic EL display device 50a according to this embodiment will be next described. The method for manufacturing the organic EL display device 50a includes a step of forming a TFT layer.

### Step of Forming TFT Layer

The TFT layer 20a is formed by forming, through a well-known method for instance, the base coat film 11, the first TFTs 9a, the second TFTs 9b, the capacitors 9c, the flattening film 19, and other components onto the surface of the resin substrate 10 formed on, for instance, a glass substrate. Here, the step of forming the TFT layer according to this embodiment includes a step of forming lower wiring layers, a rework step, a step of forming an interlayer insulating film, and a step of forming upper wiring layers.

### Step of Forming Lower Wiring Layers

The substrate surface including layers below the lower wiring layers La undergoes, for instance, photolithography to form a lower metal film, followed by patterning the lower metal film to form the lower wiring layers La (e.g., the first wiring layer, such as the gate lines 14, or the second wiring layer). A plurality of lower wiring layers La is formed in one direction (first direction X) so as to extend in parallel with each other. At this time, as illustrated in FIG. 4, the protrusion Ld protruding from at least one of the ends (both ends in FIG. 4) of the lower wiring layer La in the width direction is formed at the end between design wires of the upper wiring layers U intersecting with the lower wiring layer La. To be specific, the pattern shape of the lower wiring layers La is changed to a shape including the protrusions Ld.

### Rework Step

The rework step is a step of removing the residue (a film residue of the lower metal film) Lar (see FIG. 4) of the lower wiring layer La, as described above. The first step is forming the rework resist Rrw onto the substrate surface including the lower wiring layers La, followed by patterning the resist Rrw along the design pattern shape of the lower wiring layers La. The next is removing the residue Lar of the lower wiring layer La in a portion not covered with the resist Rrw after the patterning (see FIGS. 7 and 8).

### Step of Forming Interlayer Insulating Film

The substrate surface including the lower wiring layers La undergoes, for instance, plasma chemical vapor deposition (CVD) to form an inorganic insulating monolayer film or multilayer film, followed by patterning this inorganic insulating film as necessary, to form the interlayer insulating film IL. At this time, the interlayer insulating film IL is formed so as to cover the lower wiring layers La (see FIGS. 9 and 10).

### Step of Forming Upper Wiring Layers

The substrate surface including the interlayer insulating film IL undergoes, for instance, photolithography or sputtering to form an upper metal film, followed by patterning the upper metal film to form the upper wiring layers U (e.g., the third wiring layer, such as the source lines 18f). At this time, a plurality of upper wiring layers U is formed in a direction (the second direction Y) intersecting with the lower wiring layers La so as to extend in parallel with each other (see FIGS. 11 and 12).

The method for manufacturing the organic EL display device 50a also includes a step of forming an organic EL element layer, and a step of forming a sealing film.

### Step of Forming Organic EL Element Layer

The organic EL element layer 31 is formed by forming, through a well-known method, the first electrodes 21, the edge cover 22, the organic EL layers 23 (the hole injection layer 1, the hole transport layer 2, the emission layer 3, the electron transport layer 4, and the electron injection layer 5), and the second electrode 24 onto the flattening film 19 of the TFT layer 20 formed in the step of forming the TFT layer, to form the organic EL elements 25.

### Step of Forming Sealing Film

The first step is forming an inorganic insulating film, such as a silicon nitride film, a silicon oxide film, or a silicon oxide nitride film, onto the substrate surface including the organic EL element layer 31 formed in the step of forming the organic EL element layer, through plasma CVD using CMM, which is an evaporation mask, to form the first inorganic insulating sealing film 32. The next is forming a film of an organic resin material, such as acrylic resin, onto the first inorganic insulating sealing film 32 through, for instance, ink-jet printing to form the organic sealing film 33. The next is forming an inorganic insulating film, such as a silicon nitride film, a silicon oxide film, or a silicon oxide nitride film, through plasma CVD using CMM, which is an evaporation mask, so as to cover the organic sealing film 33, to thus form the second inorganic insulating sealing film 34, thus forming the sealing film 35. Through the foregoing process steps, the sealing film 35 having a stack of, in sequence, the first inorganic insulating sealing film 32, organic sealing film 33, and second inorganic insulating sealing film 34 can be formed in the display region D.

The final step is attaching a protective sheet (not shown) to the substrate surface, followed by laser light irradiation from near the glass substrate of the resin substrate 10 to thus remove the glass substrate from the lower surface of the resin substrate 10, followed by attaching a protective sheet (not shown) to the lower surface of the resin substrate 10 with the glass substrate removed therefrom. The organic EL display device 50a can be manufactured through the foregoing process steps.

### Effects

As described above, the organic EL display device 50a and the method for manufacturing the same according to this embodiment can achieve the following effects.

(1) The organic EL display device 50a includes the TFT layer 20a having a stack of, in sequence, the lower wiring layers La, the interlayer insulating film IL, and the upper wiring layers U intersecting with the lower wiring layers La, wherein between the upper wiring layers U adjacent to each other, at least one end of each of the lower wiring layers La in the width direction includes the protrusion Ld dividing the straightness of the end. The dividing end ELd formed in the protrusion Ld blocks a leakage path between the residue Ur and the upper wiring layer U even if the residue Ur of the upper wiring layer U remains on the interlayer insulating film IL along the etching end ELe of the lower wiring layer La; here, the residue Ur remains due to the alignment deviation M of the rework resist Rrw in the rework step for the lower wiring layer La. As described, the TFT layer 20a can prevent leakage between the upper wiring layers U even if the residue Ur of the upper wiring layer U remains.

(2) The method for manufacturing the organic EL display device 50a includes the step of forming the TFT layer (step of forming its lower wiring layers) that is similar to a conventional step, wherein the pattern shape of the lower wiring layers La only needs to be changed to a shape including the protrusions Ld; thus, the method does not require additional process steps or other things. Accordingly, the method for manufacturing the organic EL display device 50a adopts a conventionally known process step and exhibits high workability.

### Second Embodiment

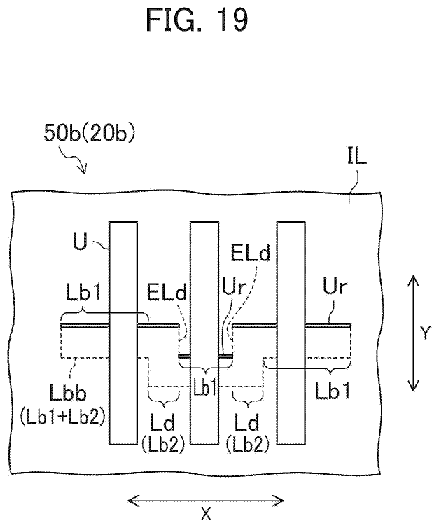

The following describes a second embodiment of the present invention with reference to FIG. 19. FIG. 19 is an enlarged plan view of a wiring structure including the upper wiring layers U after patterning, in a step of forming a TFT layer in a method for manufacturing an organic EL display device 50b according to this embodiment. The overall configuration of the organic EL display device 50b is the same as that of the first embodiment except the configuration of a TFT layer 20b; accordingly, its detailed description will be omitted here. Further, components similar to those in the first embodiment will be denoted by the same signs, and their descriptions will be omitted.

The organic EL display device 50b includes lower wiring layers Lbb constituting the TFT layer 20b; as illustrated in FIG. 19, the shape of each lower wiring layer Lbb is different in plan view from the shape of each lower wiring layer La constituting the TFT layer 20a of the organic EL display device 50a. Hence, the configuration of the protrusion Ld or recess Ld is also different. To be specific, the lower wiring layer Lbb is provided, as illustrated in FIG. 19, such that a plurality of first lower wiring layers Lb1 provided so as to extend in parallel with each other in the first direction X, and a plurality of second lower wiring layers Lb2 provided so as to extend in parallel with each other in the second direction Y intersecting with the plurality of first lower wiring layers Lb1 are continuous alternately in plan view. The lower wiring layer Lbb is provided in the form of, for instance, a recess, a protrusion, or a combination of a recess and protrusion in plan view. As described, unlike the lower wiring layer La, which extends in a straight line in the first direction X, the lower wiring layer Lbb at the location of the second lower wiring layers Lb2 extends in a straight line in the second direction Y.

It is noted that the direction in which the second lower wiring layers Lb2 extend is not limited to the second direction Y intersecting with the first lower wiring layers Lb1; the second lower wiring layers Lb2 may extend in a direction different from the first direction X (e.g., a direction inclined with respect to the first direction X and second direction Y in plan view).

Moreover, the organic EL display device 50b includes the protrusions Ld or recesses Ld included in the second lower wiring layers Lb2. To be specific, the recesses Ld are provided at an end (the upper end in FIG. 19) corresponding to the etching end ELe of the lower wiring layer La and to the end EIL of the interlayer insulating film IL, and the protrusions Ld are provided at the opposite end. It is noted that what are provided at the end corresponding to the etching end ELe of the lower wiring layer La and to the end EIL of the interlayer insulating film IL are not limited to the recesses Ld; the protrusions Ld may be provided at this end. Each recess Ld, which is included in the second lower wiring layer Lb2, likewise includes a dividing surface ELd, and at this dividing surface ELd, the straightness of the end of the first lower wiring layer Lb1 is divided. To be specific, as illustrated in FIG. 19, the recess Ld includes the dividing end ELd extending in a direction (the second direction Y in FIG. 19) turned around from the first direction X, in which the etching end ELe of the first lower wiring layer La extends. The end surface (etching end surface) of the first lower wiring layer Lb1 close to the dividing end ELd is divided (separated) by the dividing end ELd so as to be spaced in the second direction Y to be thus discontinuous in the first direction X. As described, the second lower wiring layer Lb2 constituting the protrusion Ld or recess Ld divides the straightness of the etching end ELe at the dividing end ELd by turning around to the second direction Y different from the direction along the etching end surface of the etching end ELe (i.e., the first direction X in which the first lower wiring layer Lb1 extends). In the wiring structure of the TFT layer 20b constituting the organic EL display device 50b, a leakage path formed by the residue Ur is blocked at the protrusion Ld or recess Ld (its dividing end ELd) even when the residue Ur of the upper wiring layer U remains; this prevents leakage between the upper wiring layers U.

As described, unlike the conventional wiring structure, the TFT layer 20b constituting the organic EL display device 50b includes the protrusions or recesses Ld (the second lower wiring layer Lb2) at both ends (both sides) of the first lower wiring layer Lb1 in the width direction between the plurality of upper wiring layers U adjacent to each other, as illustrated in FIG. 19; here, the protrusions or recesses divide the straightness of each end.

The organic EL display device 50b can be manufactured by changing the pattern shape of the lower wiring layers Lbb such that the first lower wiring layer Lb1 and the second lower wiring layer Lb2 are continuous alternately, in the step of forming the lower wiring layers in the step of forming the TFT layer for the foregoing organic EL display device 50a.

### Effects

The foregoing organic EL display device 50b can achieve effects similar to the earlier described effects (1) and (2).

### Other Embodiments

Although the inorganic stacked film in the foregoing embodiments includes four layers: a base coat film; and a gate insulating film, a first interlayer insulating film, and a second interlayer insulating film sequentially stacked on the base coat film, the inorganic stacked film may include a single layer: a base coat film, or include two layers: a base coat film and a gate insulating film.

Although the foregoing embodiments have each described, by way of example, an organic EL layer having a five-ply stacked structure of a hole injection layer, a hole transport layer, an emission layer, an electron transport layer, and an electron injection layer, the organic EL layer may have, for instance, a three-ply stacked structure of a hole injection-and-transport layer, an emission layer, and an electron transport-and-injection layer.

Further, although the foregoing embodiments have each described, by way of example, an organic EL display device having a first electrode as an anode, and a second electrode as a cathode, the present invention is also applicable to an organic EL display device with the stacked structure of its organic EL layer being inverted: a first electrode as a cathode, and a second electrode as an anode.

Although the foregoing embodiments have each described, by way of example, an organic EL display device in which a TFT's electrode connected to the first electrode constitutes a drain electrode, the present invention is also applicable to an organic EL display device in which a TFT's electrode connected to the first electrode constitutes a source electrode.

Although the foregoing embodiments have each described an organic EL display device as a display device by way of example, the present invention is also applicable to a display device, such as a liquid crystal display device that operates in an active matrix driving scheme.

Although the foregoing embodiments have each described an organic EL display device as a display device by way of example, the present invention is applicable to flexible display devices, as well as organic EL display devices. For instance, the present invention is applicable to a flexible display device including, but not limited to, quantum-dot light-emitting diodes (QLEDs), which are light-emitting elements including a quantum-dot-containing layer.

### INDUSTRIAL APPLICABILITY

As described above, the present invention is useful for flexible display devices.

### REFERENCE SIGNS LIST

IL interlayer insulating film
La, Lbb lower wiring layer
Ld protrusion (protrusion or recess)
Ld1, Ld2, Ld3 protrusion
Ld4 recess
U upper wiring layer
X first direction
Y second direction
10 resin substrate (base substrate)
20a, 20b TFT (thin-film transistor) layer
25 organic EL element (light-emitting element) 31 organic EL element layer (light-emitting element layer)
35 sealing film
50a, 50b organic EL display device

1. A display device comprising:
a base substrate; and
a thin-film transistor layer provided on the base substrate,
the thin-film transistor layer including
a plurality of lower wiring layers provided so as to extend in parallel with each other in a first direction in a plan view,
an interlayer insulating film provided so as to cover the plurality of lower wiring layers, and
a plurality of upper wiring layers provided on the interlayer insulating film so as to extend in parallel with each other in a second direction intersecting with the plurality of lower wiring layers,
wherein between the plurality of upper wiring layers adjacent to each other, at least one end of the plurality of lower wiring layers in the second direction includes one or more protrusions protruding with respect to the first direction in the plan view, or one or more recesses recessed with respect to the first direction in the plan view, and
the thin-film transistor layer includes
a first wiring layer, and
a second wiring layer above the first wiring layer, and
wherein the plurality of lower wiring layers is formed in a same layer with a same material as the first wiring layer or the second wiring layer.

2. The display device according to claim 1, wherein the one or more protrusions or the one or more recesses are provided at both ends of the plurality of lower wiring layers in the second direction.

3. The display device according to claim 1, wherein the one or more protrusions or the one or more recesses have a triangular shape, a rectangular shape, or a semicircular shape in the plan view.

4. The display device according to claim 1, wherein
the plurality of lower wiring layers is provided such that first lower wiring layers provided so as to extend in parallel with each other in the first direction, and second lower wiring layers provided so as to extend in parallel with each other in a direction different from the first direction are continuous alternately, and
the one or more protrusions or the one or more recesses are included in the second lower wiring layers.

5. The display device according to claim 4, wherein the second lower wiring layers are provided so as to extend in parallel with each other in the second direction intersecting with the first lower wiring layers.

6. (canceled)

7. The display device according to claim 1, wherein the plurality of lower wiring layers is a gate line formed as the first wiring layer.

8. The display device according to claim 1, wherein
the thin-film transistor layer includes a third wiring layer above the second wiring layer, and
the plurality of upper wiring layers is formed in a same layer with a same material as the third wiring layer.

9. The display device according to claim 8, wherein the plurality of upper wiring layers is a source line formed as the third wiring layer.

10. The display device according to claim 1, comprising:
a light-emitting element layer provided on the thin-film transistor layer; and
a sealing film provided so as to cover the light-emitting element layer.

11. The display device according to claim 10, wherein the light-emitting element layer is an organic electroluminescence element layer.

12. A method for manufacturing a display device,
the display device including
a base substrate, and
a thin-film transistor layer provided on the base substrate,
the thin-film transistor layer including
a plurality of lower wiring layers provided so as to extend in parallel with each other in a first direction in a plan view,
an interlayer insulating film provided so as to cover the plurality of lower wiring layers, and
a plurality of upper wiring layers provided on the interlayer insulating film so as to extend in parallel with each other in a second direction intersecting with the plurality of lower wiring layers,
the method comprising a step of forming the thin-film transistor layer onto the base substrate, the step comprising:
a step of forming the plurality of lower wiring layers by forming a lower metal film onto a substrate surface including layers below the plurality of lower wiring layers, followed by patterning the lower metal film;
a step of forming the interlayer insulating film onto the substrate surface including the plurality of lower wiring layers, so as to cover the plurality of lower wiring layers; and
a step of forming the plurality of upper wiring layers by forming an upper metal film onto the substrate surface including the interlayer insulating film, followed by patterning the upper metal film,
wherein the step of forming the plurality of lower wiring layers includes forming one or more protrusions protruding with respect to the first direction in the plan view, or one or more recesses recessed with respect to the first direction in the plan view, onto at least one end of the plurality of lower wiring layers in the second direction between the plurality of upper wiring layers adjacent to each other,
the method for manufacturing the display device further comprising, after the step of forming the plurality of lower wiring layers and before the step of forming the interlayer insulating film, a rework step of forming a rework resist onto the substrate surface including the plurality of lower wiring layers, followed by patterning along a design pattern shape of the plurality of lower wiring layers, followed by etching to remove a residue of the plurality of lower wiring layers in a portion not covered with the rework resist.

13. The method for manufacturing the display device according to claim 12, wherein
the step of forming the plurality of lower wiring layers includes forming the plurality of lower wiring layers such that first lower wiring layers extending in parallel with each other in the first direction, and second lower wiring layers extending in parallel with each other in a direction different from the first direction and constituting the one or more protrusions or the one or more recesses are continuous alternately.

14. (canceled)

15. A display device comprising:
a base substrate; and
a thin-film transistor layer provided on the base substrate,
the thin-film transistor layer including
a plurality of lower wiring layers provided so as to extend in parallel with each other in a first direction in a plan view,
an interlayer insulating film provided so as to cover the plurality of lower wiring layers, and
a plurality of upper wiring layers provided on the interlayer insulating film so as to extend in parallel with each other in a second direction intersecting with the plurality of lower wiring layers,
wherein between the plurality of upper wiring layers adjacent to each other, at least one end of the plurality of lower wiring layers in the second direction includes one or more protrusions protruding with respect to the first direction in the plan view, or one or more recesses recessed with respect to the first direction in the plan view,
the display device further comprising:
a light-emitting element layer provided on the thin-film transistor layer; and
a sealing film provided so as to cover the light-emitting element layer.

16. The display device according to claim 15, wherein the one or more protrusions or the one or more recesses are provided at both ends of the plurality of lower wiring layers in the second direction.

17. The display device according to claim 15, wherein the one or more protrusions or the one or more recesses have a triangular shape, a rectangular shape, or a semicircular shape in the plan view.

18. The display device according to claim 15, wherein
the plurality of lower wiring layers is provided such that first lower wiring layers provided so as to extend in parallel with each other in the first direction, and second lower wiring layers provided so as to extend in parallel with each other in a direction different from the first direction are continuous alternately, and
the one or more protrusions or the one or more recesses are included in the second lower wiring layers.

19. The display device according to claim 18, wherein the second lower wiring layers are provided so as to extend in parallel with each other in the second direction intersecting with the first lower wiring layers.

20. The display device according to claim 15, wherein the light-emitting element layer is an organic electroluminescence element layer.
